(19) United States
(12) Patent Application Publication
(10) Pub. No.: US 2018/0080992 A1
(43) Pub. Date: Mar. 22, 2018

(54) DETERMINATION OF A BATTERY-MODEL PARAMETER

(71) Applicant: Apple Inc., Cupertino, CA (US)

(72) Inventors: Karthik KADIRVEL, Cupertino, CA (US); Saroj SAHU, Fremont, CA (US)

(21) Appl. No.: 15/442,901

(22) Filed: Feb. 27, 2017

Related U.S. Application Data
(60) Provisional application No. 62/397,594, filed on Sep. 21, 2016.

(51) Int. Cl. G01R 31/36

(52) U.S. Cl. CPC G01R 31/3651; G01R 31/3662; G01R 31/3624

(57) ABSTRACT

A battery management unit may measure a battery voltage of a battery across a first pair of nodes of the battery management unit to produce a first battery measurement and a current of the battery based on a voltage across a second pair of nodes of the battery management unit. Then, the battery management unit may generate a threshold current for a comparator in the battery management unit based on the current, where the threshold current is a sum of the current and a predetermined reference current associated with a predetermined operating profile of an application. Next, the battery management unit may measure the first voltage when the current equals the threshold current to produce a second battery measurement. Moreover, the battery management unit may calculate a model parameter in a model of the battery based on the first voltage measurement, the second voltage measurement, and the predetermined reference current.

### CROSS-REFERENCE TO RELATED APPLICATIONS

The present application claims the benefit of U.S. Provisional Application No. 62/397,594, entitled “DETERMINATION OF A BATTERY-MODEL PARAMETER” filed Sep. 21, 2016, the content of which is incorporated herein by reference in its entirety for all purposes.

### FIELD

The described embodiments generally relate to measurement techniques. More specifically, the disclosure is directed to techniques for measuring model parameters for a battery and prediction of battery-usage parameters based on the model.

### BACKGROUND

Portable electronic devices are becoming increasingly popular, which has resulted in demand for improved performance and additional features. Most portable electronic devices are powered by energy sources, such as batteries.

Batteries convert chemical energy into electrical energy to power a portable electronic device in various operational modes. A battery is typically designed to have particular power, voltage, and current ratings that relate to a capacity of the battery to supply charge to a portable electronic device during use. For example, lithium-ion batteries are popular among device manufactures because of their high energy density and low rate of self-discharge.

However, battery performance in the portable electronic devices often limits the overall device performance. In particular, battery capacity and energy density have not increased as rapidly as the demands for additional power in portable electronic devices. Consequently, it can be challenging to maintain a portable electronic device as the power consumption of the electronic device is increased because of new features or capabilities.

In order to address this challenge, a variety of power-management techniques are typically used in portable electronic devices. Typically, in a power-management technique, a model of the battery is used to predict various battery-usage parameters, such as run time, time to empty (which is sometimes referred to as ‘battery life’) and a maximum load current that can be drawn. The values of the parameters in the battery model (which are sometimes referred to as ‘model parameters’) are typically a function of the state of charge of the battery (such as the battery capacity), the age of the battery, the temperature, as well as other factors (such as the battery manufacturer). Consequently, the model parameters may need to be updated throughout the life of the battery.

Moreover, errors in the model parameters can result in corresponding errors in the predicted battery-usage parameters, such as the time to empty (i.e., how much battery energy remains). Because users often depend on the estimated battery-usage parameters to determine when to recharge batteries, to select the features on a portable electronic device that they can use, and to determine how much longer a portable electronic device will continue to operate, the errors in the accuracy of the battery model can be very frustrating to users. Consequently, these errors can significantly degrade the user experience when using portable electronic devices.

### SUMMARY

This application describes various embodiments related to an electronic device that includes an energy-storage device management unit and an energy-storage device that powers the electronic device. The energy-storage device management unit may include a first pair of nodes and a second pair of nodes. During operation of the energy-storage device management unit, the first pair of nodes may be used to measure battery voltages across the energy-storage device and the second pair of nodes may be used to measure voltages corresponding to currents through a sense resistor that is in series with the energy-storage device. In particular, the energy-storage device management unit may initially measure a battery voltage across the first pair of nodes to produce a battery voltage measurement value and a load current based on a second voltage across a second pair of nodes, the first pair of nodes being connected to the energy-storage device in the electronic device and the second pair of nodes being connected to a sense resistor that is connected to a first node of the first pair of nodes. Then, based on the load current, the energy-storage device management unit may generate a threshold current for a comparator in the energy-storage device management unit, where the threshold current is a sum of a load-related current and a reference current. The load-related current may be a value produced by a voltage-to-current converter representing a scaled value of the load current. Subsequently, when the load-related current is not less than the threshold current, the energy-storage device management unit may measure the battery voltage again to produce a second battery voltage measurement value. Next, the energy-storage device management unit may calculate a series resistance in a model of the energy-storage device based on the battery voltage measurement value, the second battery voltage measurement value, and the reference current.

Moreover, the energy-storage device management unit may use the model of the energy-storage device to estimate an energy-storage device-usage parameter, such as the life (e.g., time to empty) of the energy-storage device, the run time, or the maximum load current that can be drawn from the energy-storage device.

Furthermore, the energy-storage device management unit may include an analog-to-digital converter that measures the first battery voltage measurement value and the second battery voltage measurement value. Additionally, the energy-storage device management unit may measure a second voltage across the second pair of nodes that corresponds to the load current using the analog-to-digital converter.

The energy-storage device management unit may include a voltage-to-current converter that converts the second voltage across the sense resistor from the second pair of nodes into a load-related current that is applied to an input of the comparator. The load-related current may be a scaled value that represents the load current. Moreover, the energy-storage device management unit may create or generate the threshold current by summing the reference current and the load-related current using a summation circuit (such as an analog summation circuit).

In some embodiments, the energy-storage device management unit may access a predetermined operating profile of the energy-storage device based on an application executing on the electronic device or a state of the processor of the electronic device. This predetermined operating profile may include values that correspond to reference currents to be applied depending on the application executing on the electronic device or the current state of the processor. Additionally, the predetermined operating profile may include values of the load current or the load-related current. Therefore, the reference current may be predefined or predetermined, and the energy-storage device management unit may calculate the series resistance in the model of the energy-storage device based on the first battery voltage measurement value, the second battery voltage measurement value and the predetermined operating profile, i.e., without measuring the load current using the analog-to-digital converter. For example, the energy-storage device management unit may calculate the series resistance in the model of the energy-storage device based on the first voltage measurement value, the second voltage measurement value, and the reference current specified in the predetermined operating profile.

Other embodiments describe the energy-storage device management unit.

Other embodiments describe a computer-readable storage medium including instructions which, when executed by one or more processors of an electronic device, cause the electronic device to perform at least some of the aforementioned operations.

Other embodiments provide a method of determining a model parameter in a model of an energy-storage device. The method includes at least some of the aforementioned operations performed by the electronic device.

This Summary is provided for purposes of illustrating some exemplary embodiments, so as to provide a basic understanding of some aspects of the subject matter described herein. Accordingly, it will be appreciated that the above-described features are only examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

The included drawings are for illustrative purposes and serve only to provide examples of possible structures and arrangements for the disclosed systems and techniques for measuring model parameters for a battery and prediction of battery-usage parameters based on the model. These drawings in no way limit any changes in form and detail that may be made to the embodiments by one skilled in the art without departing from the spirit and scope of the embodiments. The embodiments will be readily understood by the following detailed description in conjunction with the accompanying drawings, wherein like reference numerals designate like structural elements.

FIG. 1 is a drawing illustrating an example of a lumped-element model of a battery, according to some embodiments.

FIG. 2A is a block diagram illustrating an example of a battery management unit, according to some embodiments.

FIG. 2B depicts a reference table including application specific reference currents, according to some embodiments.

FIG. 3 is a flow diagram illustrating an example of a method for determining a model parameter in a model of a battery, according to some embodiments.

FIG. 4 is a block diagram illustrating an example of an electronic device, according to some embodiments.

Note that like reference numerals refer to corresponding parts throughout the drawings. Moreover, multiple instances of the same part are designated by a common prefix separated from an instance number by a dash.

### DETAILED DESCRIPTION

A battery management unit in an electronic device is described. At a first time, the battery management unit may measure a battery voltage of a battery across a first pair of nodes of the battery management unit to produce a first battery voltage measurement value and a load current based on a second voltage across a second pair of nodes of the battery management unit. Then, the battery management unit may generate a threshold current for a comparator in the battery management unit based on a load-related current, where the threshold current is a sum of the load-related current and a predetermined reference current associated with a predetermined operating profile of an application. The load-related current may be a scaled value representing the load current that is produced by the voltage-to-current converter. Next, the battery management unit may measure, at a second time, the battery voltage when the load-related current equals or exceeds the threshold current to produce a second battery voltage measurement value. In one example, the load-related current may become equal or exceed the threshold current when an application executing on the electronic device increases its energy consumption. For example, during the use of a gaming application, an increase in user input could cause an increase in processor usage and an increase in energy consumption of the energy-storage device. Moreover, the battery management unit may calculate a model parameter in a model of the battery based on the battery voltage measurement value, the second battery voltage measurement value and the predetermined reference current.

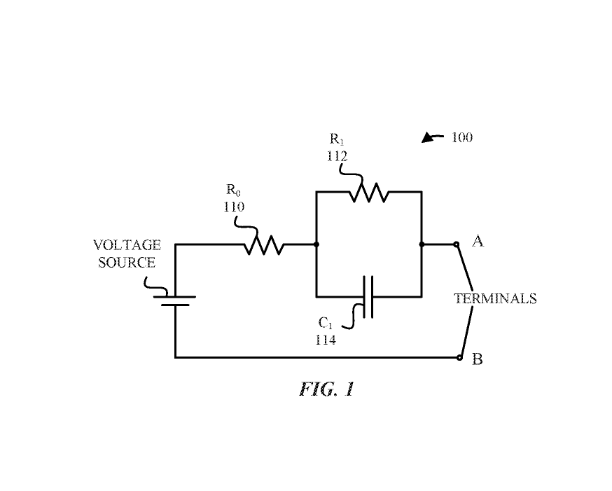

This application provides a way to avoid constantly measuring the battery voltage yet allows the model parameter (for example, R₀ in FIG. 1) of the battery to be determined, thereby reducing power consumption. In addition, the battery management unit may be less complicated and the model parameter may be determined more accurately. The more accurate determination of the model parameter may, in turn, improve the accuracy of estimated battery-usage parameters, such as time until empty for the battery or the remaining usage time. Consequently, the measurement technique may reduce user frustration when using the electronic device, and therefore may improve the user experience when using the electronic device.

In the discussion that follows, the electronic device includes or is sometimes referred to as: a ‘portable electronic device,’ a ‘mobile device,’ a ‘mobile electronic device,’ a computing device,’ a ‘mobile computing device,’ a ‘consumer electronic device,’ a ‘wireless communication device,’ ‘mobile station,’ ‘wireless station,’ ‘station,’ and ‘user equipment.’ These phrases may be used equivalently to describe electronic devices that may be capable of performing procedures associated with various embodiments of the disclosure. In the discussion that follows, a portable electronic device, such as a cellular telephone, is used as an illustration of the electronic device. However, the portable electronic device may include a variety of different electronic devices, such as: a laptop computer, a tablet computer, a music player, a mixed-media playback device, a smart watch, a wearable device or monitor, a mobile hotspot device, a health monitoring device, etc.

Moreover, in the discussion that follows, a battery is used as an illustration of an energy-storage device that has an impedance. However, in other embodiments the measurement technique may be used with a variety of energy-storage devices, including: a capacitor, a fuel cell, a rechargeable energy-storage device, a non-rechargeable energy-storage device, etc.

We now describe embodiments of the measurement technique. FIG. 1 presents a drawing illustrating an example of a lumped-element RC model 100 of a battery, including a voltage source, a series resistor (R₀) 110, and a resistor (R₁) 112 in parallel with a capacitor (C₁) 114, according to some embodiments. This model may be used to estimate battery-usage parameters (such as a battery life, battery capacity, etc.), e.g., for use in a feedback technique or a power-management technique in an electronic device. Note that the accuracy of predictions based on model 100 are typically very sensitive to R₀ 110. Also note that R₀ 110 may be battery specific, i.e., it may vary from battery to battery, and it may vary as a function of time and usage.

One approach for determining values of the circuit components or model parameters in model 100 is to apply a high frequency pulse to the battery, so that R₀ 110 dominates in model 100 because C₁ 114 appears as a short. In this case, R₀ 110 can be computed as the ratio of the measured voltage to the measured current when a high-frequency pulse is applied to the battery. Series resistor (R₀) 110 can then be used to estimate energy-storage device parameters (e.g., time to empty).

However, existing approaches for measuring the model parameters in model 100 often require: high processing power, large memory requirements and/or large current consumption. For example, front-end circuits in the electronic device usually need to have large dynamic range in order to measure the large pulse, which in turn leads to large current consumption. Consequently, the existing approaches for determining the model parameters can increase the cost and complexity of an electronic device that includes the battery.

In order to address these challenges, a battery management unit in the electronic device may perform a measurement technique that facilitates low-power and accurate determination of the model parameters and, thus, accurate modeling of the battery-usage parameters.

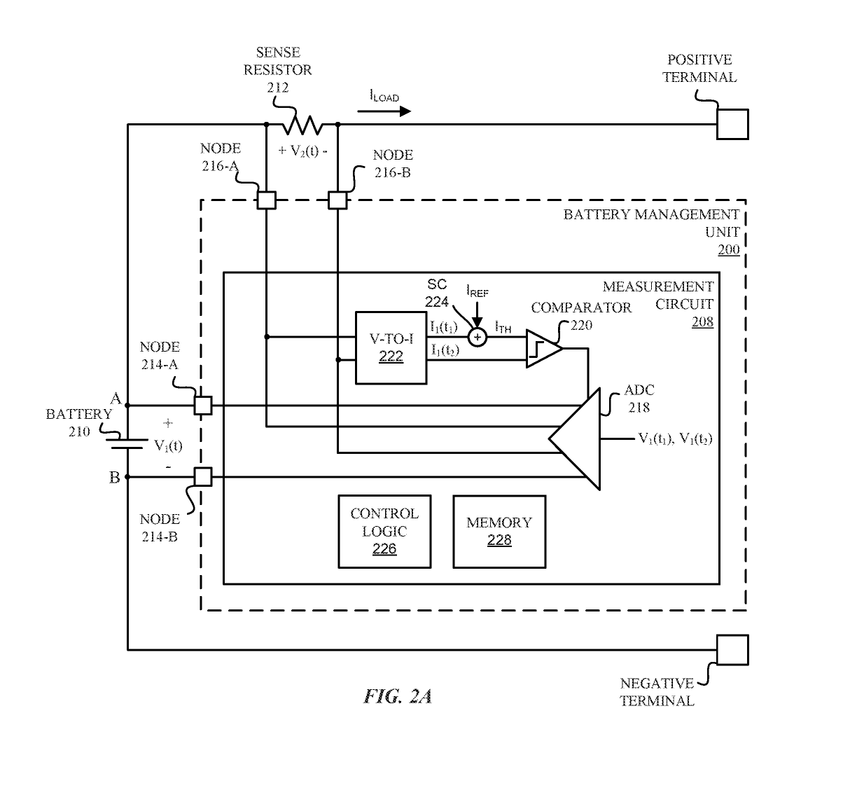

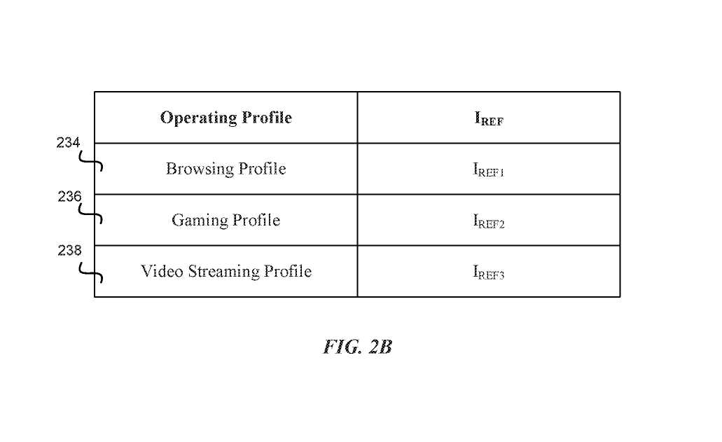

FIG. 2A presents a block diagram illustrating an example of a battery management unit 200. Battery terminals A and B of battery 210 correspond to terminals A and B of model 100. In one example, battery 210 is modeled according to model 100. This battery management unit may a include pair of nodes, 214-A and 214-B, and a second pair of nodes, 216-A and 216-B. During operation of battery management unit 200, the nodes 214-A and 214-B may be used to measure a battery voltage V₁(t) across the battery 210 at various times and nodes 216-A and 216-B may be used to directly sense a load current I_{LOAD} through a sense resistor 212 that is in series with battery 210 or to indirectly sense the load current based on a second voltage V₂(t) that corresponds to the battery current I_{LOAD}.

In particular, at a first or an initial time t₁ (such as during a calibration operating mode), a measurement circuit 208 in battery management unit 200 may measure the battery voltage V₁(t₁) and the load current I_{LOAD}. For example, measurement circuit 208 may include an analog-to-digital converter (ADC) 218 that measures V₁(t₁) and I_{LOAD} (or the second voltage V₂(t₁) that is used to determine I_{LOAD} based on a value of sense resistor 212). In some embodiments, second voltage V₂(t) is converted into load current I_{LOAD} using a voltage-to-current converter (V-to-I) 222. V-to-I may then output the scaled signal I₁(t) that represents I_{LOAD}. In some embodiments, I₁(t) may be a scaled signal that represents I_{LOAD} sampled at a first or second time.

Then, based on I₁(t₁), control logic 226 of the measurement circuit 208 may generate a threshold current (I_{TH}) for a comparator 220 in measurement circuit 208, where I_{TH} is a sum of I₁(t₁) and a reference current I_{REF}. For example, measurement circuit 208 may include a V-to-I 222 that converts the second voltage V₂(t) across sense resistor 212 from pair of nodes 216-A and 216-B into the load current I_{LOAD} and output a load-related current, I₁(t₁), that is applied to an input of comparator 220. As previously discussed, I₁(t₁) may be a scaled signal that represents I_{LOAD}. Moreover, measurement circuit 208 may create or generate I_{TH} using summation circuit (SC) 224 by summing I_{REF} and I₁(t₁). I₁(t₁) is output by V-to-I 222 during a measurement at t₁. Note that summation circuit 224 may be an analog circuit. In some embodiments, V-to-I 222 can include a memory to store I₁(t₁) or I₁(t₁) may be stored in memory 228. I₁(t₁) may be stored in memory to produce a value for the comparator 220.

Subsequently, when comparator 220 changes state (i.e., when the load-related current I₁(t₂) equals or exceeds I_{TH}), measurement circuit 208 may measure the battery voltage V₁(t₂). For example, measurement circuit 208 may measure V₁(t₂) using ADC 218.

In some embodiments, instead of measuring I₁(t₂), battery management unit 200 (such as control logic 226) may access a predetermined operating profile of the battery based on an application (such as a program module) executing on the electronic device. This predetermined operating profile may include values of I₁(t₂), I_{LOAD} and/or I_{REF} (which may be based on a range of load currents associated with the application), and may be stored in memory 228 in battery management unit 200, such as in a look-up table that includes application identifiers and corresponding predetermined operating profiles. Therefore, I_{REF} may be predefined or predetermined. Note that control logic 226 may be implemented using hardware and/or software, such as a processor that executes software (e.g., firmware). However, in some embodiments measurement circuit 208 may measure I₁(t₂) using ADC 218.

Next, battery management unit 200 (such as control logic 226) may calculate R₀ 110 in a model of battery 210 based on V₁(t₁), V₁(t₂) and I_{REF}. In particular,

$${R}_{0} = \frac{{V}_{1} ( {t}_{2} ) - {V}_{1} ( {t}_{1} )}{{I}_{REF}}$$

In embodiments with the predetermined operating profile, battery management unit 200 calculates R₀ 110 based on V₁(t₁), V₁(t₂) and the information in the predetermined operating profile (notably I_{REF}).

Moreover, battery management unit 200 (such as control logic 226) may use the model of battery 210 to estimate a battery-usage parameter, such as a battery life of the battery, run time, time to empty, or a maximum load current that can be drawn from the battery.

This measurement technique may reduce the measurements and calculations performed by battery management unit 200 because I_{REF} may be a constant and may be known to the measurement circuit 208 (e.g., via the predetermined operating profile). Moreover, the measurement technique may reduce the power consumption needed to determine R₀ 110. For example, in addition to determining R₀ 110 without measuring I₁(t₂) or I_{LOAD}, computing the difference between V₁(t₁) and V₁(t₂) may be performed using an analog circuit that has very low power consumption. However, in some embodiments the calculations are performed, at least in part, using an digital circuit. In some embodiments, the measurement technique may facilitate continuous or repeated measurements of the model parameter over short time intervals over the life of battery 210. Alternatively or additionally, the measurement technique may reduce the power consumption (and, thus, may save battery power) by only performing the measurement of V₁(t₂) and the calculation of R₀ 110 when needed (such as when the load-related current I₁(t₂), equals I_{TH}).

While FIG. 2A illustrates a particular configuration of battery management unit 200, in other embodiments there may be more or fewer components, the positions of one or more components may be changed and/or two or more components may be combined. For example, measurements may be performed in the current and/or the voltage domain, and may be performed using series and/or parallel circuits. Furthermore, the measurements may be performed using analog circuits and/or digital circuits. In some embodiments, there are multiple instances of measurement circuit 208, each of which may be set to a different value of I_{REF}. However, in other embodiments, the value of I_{REF} in measurement circuit 208 is programmable.

FIG. 2B depicts a reference table including application specific reference currents, according to some embodiments. A specific operating profile (e.g., browsing profile 234) can be used for applications relating to the profile (e.g. Internet applications, news applications, and the like can each use the browsing profile 234). Each operating profile can correspond to one or more reference currents that can be applied to the summation circuit 224. For example, when the electronic device is using the browsing profile 234, the reference current I_{REF1} can be used by the battery management unit 200 to determine the model parameter R₀. Similarly, when the gaming profile 236 is being used, reference current I_{REF2}, can be used to determine the model parameter R₀. Additionally, when the video streaming profile 238 is being used, reference current I_{REF3} can be used to determine the model parameter R₀. In other embodiments, specific reference current values can be based on a state of a processor or an application executing on a processor.

In other embodiments, a specific operating profile includes a set of values for the reference current based on the specific device. For example, when the electronic device is a cellular telephone, the values of the reference current may be 1, 2 and 3 A. Similarly, when the electronic device is a tablet computer, the values of the reference current may be 0.5, 3 and 4 A. Then, during the measurement technique, the different values of the reference current may be used to determine corresponding values of the series resistance in the battery model. In general, the values of the reference current may be determined heuristically.

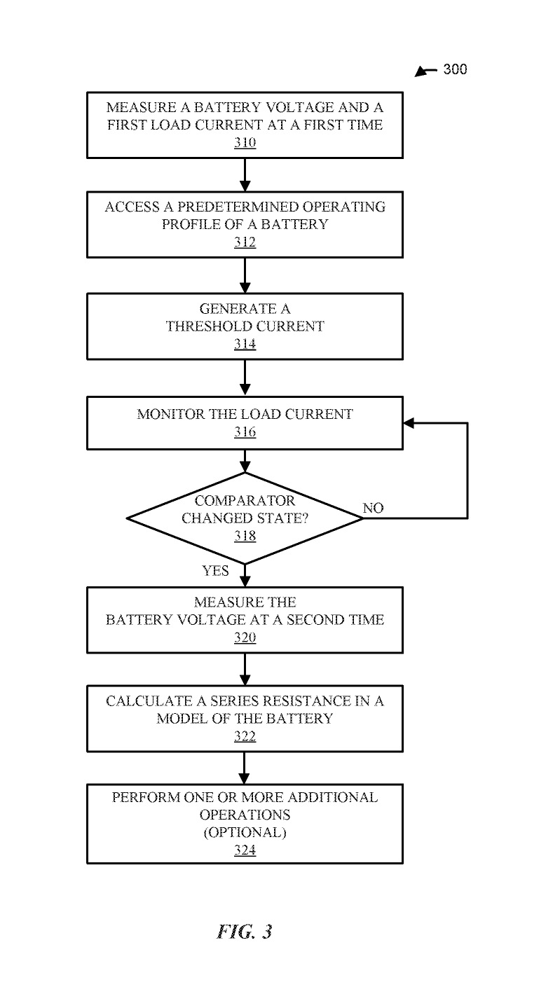

FIG. 3 presents a flow diagram illustrating an example of a method 300 for determining a model parameter in a model of a battery, which may be performed by a battery management unit (such as battery management unit 200 in FIG. 2). During operation, the battery management unit may measure, at a first time, a battery voltage (operation 310) across a first pair of nodes of the battery management unit to produce a first battery voltage measurement value and a load current (operation 310) based on a second voltage across a second pair of nodes of the battery management unit, where the first pair of nodes permit measurement of a battery voltage across the battery and the second pair of nodes permit measurement of a second voltage corresponding to the load current through a sense resistor that is in series with the battery.

For example, the battery management unit may include an analog-to-digital converter that measures the battery voltage and the load current (or a voltage across the second pair of nodes that corresponds to the load current). Moreover, the battery management unit may include a voltage-to-current converter that converts second voltage across the sense resistor from the second pair of nodes into the load current and outputs a scaled signal, the load-related current, which is applied to an input of the comparator.

In some embodiments, the battery management unit may access a predetermined operating profile of the battery (operation 312) based on an application executing on the electronic device. This predetermined operating profile may include values of the reference current. In one example, the reference current may be application specific.

Then, based on the load current, the battery management unit may generate a threshold current (operation 314) to be used as an input for a comparator in the battery management unit, where the threshold current is a sum of the load-related current and a reference current. For example, the battery management unit may create or generate the threshold current by summing the reference current and the load-related current using a summation circuit.

After a threshold current is established, the management circuit can monitor the load current (operation 316) at the second pair of nodes (or a battery voltage across the second pair of nodes that corresponds to the load current) to determine when the monitored load current causes a comparator to switch states (i.e., the monitored load current becomes equal to or exceeds the threshold current).

When the comparator determines, by performing the comparison of the monitored load current and the threshold current, that the load current equals or exceeds the threshold current (operation 318), the battery management unit can measure the battery voltage (operation 320) across the first pair of nodes at a second time to produce a second battery voltage measurement value. For example, the battery management unit may measure the battery voltage using the analog-to-digital converter. Otherwise, the management circuit continues to monitor the load current (operation 316) until the comparator changes states.

Next, the battery management unit may calculate a series resistance in a model of the battery (operation 322) based on the first battery voltage measurement value, the second battery voltage measurement value, and the reference current. In another embodiment, the predetermined operating profile may include values of the load current. Thus, the battery management unit may calculate the series resistance in the model of the battery based on the first battery voltage measurement value, the second battery voltage measurement value, and the predetermined operating profile, i.e., without measuring the load current using the analog-to-digital converter. For example, the battery management unit may calculate the series resistance in the model of the battery based on the first battery voltage measurement value, the second battery voltage measurement value, and the reference current specified in the predetermined operating profile. In some embodiments, method 300 includes one or more optional additional operations (operation 322). For example, the battery management unit may use the model of the battery to estimate a battery-usage parameter, such as a battery life of the battery. Moreover, when more than one application is being executed concurrently on the electronic device, the battery management unit may infer or determine the reference voltage based on the predetermined operating profiles for the one or more applications.

In some embodiments of method 300, there may be additional or fewer operations. Moreover, the order of the operations may be changed, and/or two or more operations may be combined into a single operation.

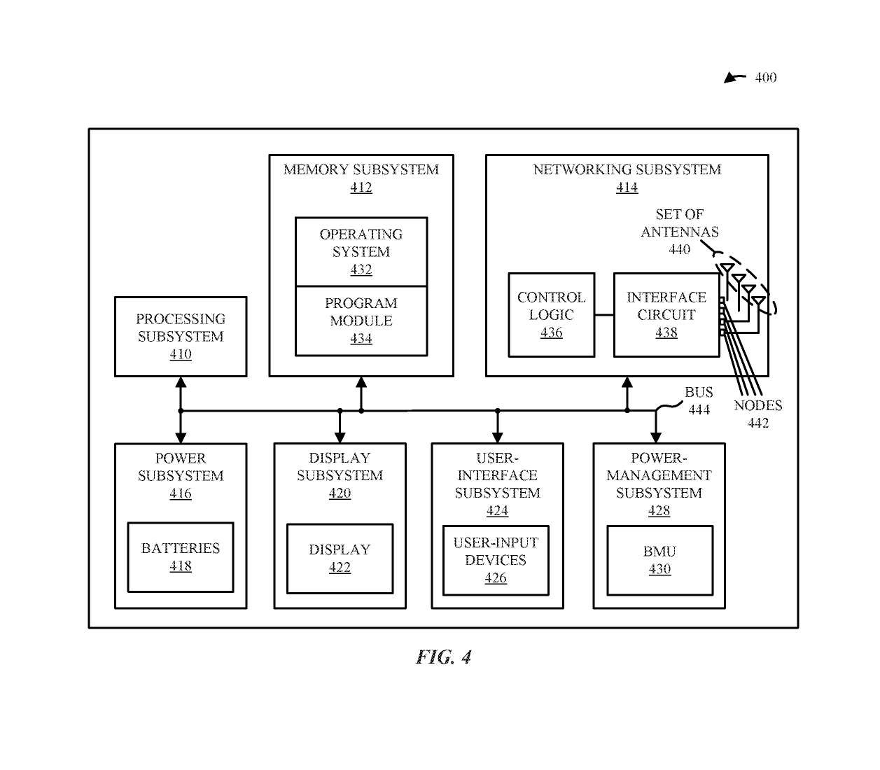

FIG. 4 presents a block diagram illustrating an example of an electronic device 400 (such as a portable electronic device) that implements the measurement technique. This electronic device may include processing subsystem 410, memory subsystem 412, networking subsystem 414, power subsystem 416, display subsystem 420, user-interface subsystem 424 and power-management subsystem 428. Processing subsystem 410 includes one or more devices configured to perform computational operations. For example, processing subsystem 410 can include one or more microprocessors (such as central processing units or CPUs), graphical processor units (GPUs), application-specific integrated circuits (ASICs), microcontrollers, programmable-logic devices, and/or one or more digital signal processors (DSPs).

Memory subsystem 412 may include one or more devices for storing data and/or instructions for processing subsystem 410 and networking subsystem 414. For example, memory subsystem 412 can include dynamic random access memory (DRAM), static random access memory (SRAM), a read-only memory (ROM), flash memory, and/or other types of memory.

Moreover, memory subsystem 412 can include mechanisms for controlling access to the memory. In some embodiments, memory subsystem 412 includes a memory hierarchy that comprises one or more caches coupled to a memory in electronic device 400. In some of these embodiments, one or more of the caches is located in processing subsystem 410.

Furthermore, memory subsystem 412 may be coupled to one or more high-capacity mass-storage devices (not shown). For example, memory subsystem 412 can be coupled to a magnetic or optical drive, a solid-state drive, or another type of mass-storage device. In these embodiments, memory subsystem 412 can be used by electronic device 400 as fast-access storage for often-used data, while the mass-storage device is used to store less frequently used data.

In some embodiments, instructions for processing subsystem 410 stored in memory subsystem 412 include: one or more applications, program modules or sets of instructions (such as one or more program modules 434 or operating system 432), which may be executed by processing subsystem 410. For example, a ROM can store programs, utilities or processes to be executed in a non-volatile manner, and DRAM can provide volatile data storage, and may store instructions related to the operation of electronic device 400. Note that the one or more computer programs may constitute a computer-program mechanism or software. Moreover, instructions in the various modules in memory subsystem 412 may be implemented in: a high-level procedural language, an object-oriented programming language, and/or in an assembly or machine language. Furthermore, the programming language may be compiled or interpreted, e.g., configurable or configured (which may be used interchangeably in this discussion), to be executed by processing subsystem 410. In some embodiments, the one or more computer programs are distributed over a network-coupled computer system so that the one or more computer programs are stored and executed in a distributed manner.

In addition, memory subsystem 412 may store information that is used in the measurement technique, such as predetermined operating profiles of one or more applications (such as one or more program modules 434) that may be executed by processing subsystem 410 and/or by one or more components in electronic device 400.

Networking subsystem 414 may include one or more devices configured to couple to and communicate on a wired and/or wireless network (i.e., to perform network operations), including: control logic 436, an interface circuit 438 and a set of antennas 440 (or antenna elements) in an adaptive array that can be selectively turned on and/or off by control logic 436 to create a variety of optional antenna patterns or ‘beam patterns.’ (While FIG. 4 includes set of antennas 440, in some embodiments electronic device 400 includes one or more nodes, such as nodes 442, e.g., a pad, which can be coupled to set of antennas 440. Thus, electronic device 400 may or may not include set of antennas 440.) For example, networking subsystem 414 can include a Bluetooth™ networking system, a cellular networking system (e.g., a 3G/4G network such as UMTS, LTE, etc.), a universal serial bus (USB) networking system, a networking system based on the standards described in IEEE 802.11 (e.g., a Wi-Fi® networking system), an Ethernet networking system, and/or another networking system.

Moreover, networking subsystem 414 may include processors, controllers, radios/antennas, sockets/plugs, and/or other devices used for coupling to, communicating on, and handling data and events for each supported networking system. Note that mechanisms used for coupling to, communicating on, and handling data and events on the network for each network system are sometimes collectively referred to as a ‘network interface’ for the network system. Moreover, in some embodiments a ‘network’ or a ‘connection’ between the electronic devices does not yet exist. Therefore, electronic device 400 may use the mechanisms in networking subsystem 414 for performing simple wireless communication between the electronic devices, e.g., transmitting advertising or beacon frames and/or scanning for advertising frames transmitted by other electronic devices. Aside from the mechanisms herein described, radios are generally known in the art and hence are not described in detail. In general, networking subsystem 414 and/or the integrated circuit can include any number of radios. Note that the radios in multiple-radio embodiments function in a similar way to the described single-radio embodiments.

Power subsystem 416 may include one or more batteries 418 that electronic device 400. For example, the one or more batteries 418 may power components in electronic device 400, such as processing subsystem 410. Note that the one or more batteries 418 may include any number of battery cells, which in turn may be connected in a parallel and/or series arrangement. Moreover, the one or more batteries 418 may include a wide variety of battery types and battery compositions.

While electronic device 400 is shown with particular components, there may be additional components, such as a camera, speakers, etc.), which may affect the power consumption of the electronic device 400 depending on whether these components are active or inactive. For example, a camera (e.g., a backward and/or a forward facing camera) may function in one or more operational modes having varying power consumption characteristics depending on settings associated with one or more of the applications. In some embodiments, the camera may operate in multiple, different operational modes, including, but not limited to including: an image burst mode, a video mode, and a photo mode (e.g., a still image capture mode). Each of these camera operational modes may have a distinct power consumption requirement of the one or more batteries 418 that uniquely affects the discharge current or energy rate.

Moreover, display subsystem 420 may display information on a display 422, which may include a display driver and the display, such as a liquid-crystal display, a multi-touch touchscreen, etc. Display subsystem 420 may be controlled by processing subsystem 410 to display information to a user. For example, display 422 may display one or indicators or icons associated with battery-charge parameters, such as an amount of accessible charge of the one or more batteries 418.

Furthermore, user-interface subsystem 424 may include one or more user-input devices 426 (such as a keyboard, a mouse, a touchpad, a touch-sensitive display, a human-interface device, etc.) that allow a user of the electronic device 400 to interact with electronic device 400. For example, user-input devices 426 can take a variety of forms, such as: a button, a keypad, a dial, a touch screen, an audio input interface, a visual/image capture input interface, an input in the form of sensor data, etc. In particular, a user may use the one or more user-input devices 426 to provide one or more user inputs that are used to adjust or change information displayed on display 422, the application(s) executed by electronic device 400, etc. Note that in some embodiments display 422 is a touch-sensitive display that is included in display subsystem 420 and in the one or more user-input devices 426.

Additionally, power-management subsystem 428 may include a battery management unit (BMU) 430 (which may be an embodiment of battery management unit 200 in FIG. 2). During the measurement technique, processing subsystem 410 may execute one or more of the program modules 432 and battery management unit 430 may perform the measurement technique in order to determine one or more model parameters for one or more of batteries 418. The one or more model parameters may be stored in battery management unit 200 and/or in memory subsystem 412. Moreover, the one or more model parameters may be used by battery management unit 200 and/or processing subsystem 410 to estimate a battery-usage parameter, such as a battery life of one or more batteries 418. In some embodiments, power-management subsystem 428 includes one or more sensors, such as a temperature sensor that determines a temperature of one or more of batteries 418 and/or an environment of electronic device 400. These environmental measurements may be used by battery management unit 200 and/or processing subsystem 410 to estimate the battery-usage parameter.

Components in electronic device 400 may be coupled together using bus 444 that facilitates data transfer between these components. Bus 444 may include an electrical, optical, and/or electro-optical connection that the subsystems can use to communicate commands and data among one another. Although only one bus 444 is shown for clarity, different embodiments can include a different number or configuration of electrical, optical, and/or electro-optical connections among the subsystems.

Electronic device 400 can be (or can be included in) any electronic device with at least one battery. For example, electronic device 400 may include: a cellular telephone or a smartphone, a tablet computer, a laptop computer, a notebook computer, a personal or desktop computer, a netbook computer, a music player, a mixed-media playback device, a media player device, an electronic book device, a MiFi® device, a smartwatch, a wearable computing device, a portable computing device, a consumer-electronic device, a wearable device or monitor, a mobile hotspot device, a health monitoring device, as well as any other type of electronic computing device.

Although specific components are used to describe electronic device 400, in alternative embodiments, different components and/or subsystems may be present in electronic device 400. For example, electronic device 400 may include one or more additional processing subsystems, memory subsystems, networking subsystems, and/or display subsystems. Additionally, one or more of the subsystems may not be present in electronic device 400. Moreover, in some embodiments, electronic device 400 may include one or more additional subsystems that are not shown in FIG. 4. Also, although separate subsystems are shown in FIG. 4, in some embodiments some or all of a given subsystem or component can be integrated into one or more of the other subsystems or component(s) in electronic device 400. For example, in some embodiments the one or more program modules 434 are included in operating system 432 and/or control logic 436 is included in interface circuit 438.

Moreover, the circuits and components in electronic device 400 may be implemented using any combination of analog and/or digital circuitry, including: bipolar, PMOS and/or NMOS gates or transistors. Furthermore, signals in these embodiments may include digital signals that have approximately discrete values and/or analog signals that have continuous values. Additionally, components and circuits may be single-ended or differential, and power supplies may be unipolar or bipolar.

An integrated circuit (which is sometimes referred to as a ‘communication circuit’) may implement some or all of the functionality of one or more components in electronic device 400. This integrated circuit may include hardware and/or software mechanisms that are used for power management in electronic device 400.

In some embodiments, an output of a process for designing the integrated circuit, or a portion of the integrated circuit, which includes one or more of the circuits described herein may be a computer-readable medium such as, for example, a magnetic tape or an optical or magnetic disk. The computer-readable medium may be encoded with data structures or other information describing circuitry that may be physically instantiated as the integrated circuit or the portion of the integrated circuit. Although various formats may be used for such encoding, these data structures are commonly written in: Caltech Intermediate Format (CIF), Calma GDS II Stream Format (GDSII) or Electronic Design Interchange Format (EDIF). Those of skill in the art of integrated circuit design can develop such data structures from schematic diagrams of the type detailed above and the corresponding descriptions and encode the data structures on the computer-readable medium. Those of skill in the art of integrated circuit fabrication can use such encoded data to fabricate integrated circuits that include one or more of the circuits described herein.

Note that examples in the preceding discussion are for illustrative purposes only. Consequently, the numerical values used are intended as non-limiting examples and the measurement technique may be used in conjunction with batteries that have a wide variation in the numerical values.

While some of the operations in the preceding embodiments were implemented in hardware or software, in general the operations in the preceding embodiments can be implemented in a wide variety of configurations and architectures. Therefore, some or all of the operations in the preceding embodiments may be performed in hardware, in software or both. For example, at least some of the operations in the measurement technique may be implemented using the one or more program modules 434 and/or operating system 432. Alternatively or additionally, at least some of the operations in the measurement technique may be implemented in a hardware, such as in power-management subsystem 428.

In the preceding description, we refer to ‘some embodiments.’ Note that ‘some embodiments’ describes a subset of all of the possible embodiments, but does not always specify the same subset of embodiments.

The foregoing description is intended to enable any person skilled in the art to make and use the disclosure, and is provided in the context of a particular application and its requirements. Moreover, the foregoing descriptions of embodiments of the present disclosure have been presented for purposes of illustration and description only. They are not intended to be exhaustive or to limit the present disclosure to the forms disclosed. Accordingly, many modifications and variations will be apparent to practitioners skilled in the art, and the general principles defined herein may be applied to other embodiments and applications without departing from the spirit and scope of the present disclosure. Additionally, the discussion of the preceding embodiments is not intended to limit the present disclosure. Thus, the present disclosure is not intended to be limited to the embodiments shown, but is to be accorded the widest scope consistent with the principles and features disclosed herein.

What is claimed is:

1. A method comprising:
at an energy-storage device management unit:
measuring a first voltage across a first pair of nodes to produce a first voltage measurement value;
measuring a current based on a second voltage across a second pair of nodes to produce a current measurement value, wherein the first pair of nodes are configured to connect to an energy-storage device in an electronic device and the second pair of nodes are connected to a sense resistor that is connected to a first node of the first pair of nodes;
generating a threshold current for a comparator, wherein the threshold current is a sum of the current measurement value and a reference current value;
when the current measurement value is not less than the threshold current value, measuring the first voltage to produce a second voltage measurement value; and
calculating a model parameter in a model of the energy-storage device based on the first voltage measurement value, the second voltage measurement value, and the reference current value.

2. The method of claim 1, wherein the method further comprises accessing an operating profile of the energy-storage device based on an application executing on the electronic device, wherein the operating profile includes a value of the reference current value.

3. The method of claim 1, wherein the method further comprises estimating an energy-storage device usage parameter of the energy-storage device based on the model and the calculated model parameter.

4. The method of claim 1, wherein the model parameter includes a series resistance in the model.

5. The method of claim 1, wherein the first voltage measurement value and the second voltage measurement value are measured using an analog-to-digital converter in the energy-storage device management unit.

6. The method of claim 1, wherein the current measurement value is measured using an voltage-to-current converter in the energy-storage device management unit that measures the second voltage across the second pair of nodes.

7. The method of claim 1, wherein the comparator in the energy-storage device management unit is used to determine when the current measurement value is not less than the threshold current value.

8. The method of claim 7, wherein, prior to determining when the current measurement value is not less than the threshold current value, the method further comprises:
converting the second voltage into a scaled value representing the current measurement value using a voltage-to-current converter; and
providing the scaled value to the comparator.

9. An energy-storage device management unit, comprising:
a first pair of nodes configured to permit measurement of a first voltage across an energy-storage device in an electronic device;
a second pair of nodes configured to permit measurement of a second voltage corresponding to a current through a sense resistor connected to a first node of the first pair of nodes;
a measurement circuit electrically coupled to the first pair of nodes and the second pair of nodes; and
control logic configured to:
measure, using the measurement circuit, the first voltage across the first pair of nodes to produce a first voltage measurement value,
measure the current through the sense resistor based on the second voltage across the second pair of nodes to produce a current measurement value,
generate a threshold current for the measurement circuit based on the current measurement value, wherein the threshold current is a sum of the current measurement value and a reference current value,
when the current measurement value is not less than the threshold current value, measure the first voltage using the measurement circuit to produce a second voltage measurement value, and
calculate a series resistance in a model of the energy-storage device based on the first voltage measurement value, the second voltage measurement value, and the reference current value.

10. The energy-storage device management unit of claim 9, wherein the measurement circuit further comprises an analog-to-digital converter electrically coupled to the first pair of nodes and the second pair of nodes; and
wherein the analog-to-digital converter is configured to measure the first voltage measurement value, the second voltage measurement value, and the current measurement value at a plurality of times.

11. The energy-storage device management unit of claim 9, wherein the measurement circuit further comprises:
a voltage-to-current converter, electrically coupled to the second pair of nodes, configured to convert the second voltage to the current measurement value; and
a comparator, electrically coupled to the voltage-to-current converter, configured to determine when the current measurement value equals or exceeds the threshold current.

12. The energy-storage device management unit of claim 9, wherein the control logic is further configured to access a operating profile of the energy-storage device based on an application executing on the electronic device; and
wherein the predetermined operating profile includes a value of the reference current value.

13. The energy-storage device management unit of claim 9, wherein the control logic is further configured to estimate an energy-storage device usage parameter of the energy-storage device based on the model and the calculated series resistance.

14. An energy-storage device management unit, comprising:
a first pair of nodes configured to permit measurement of a first voltage across an energy-storage device in an electronic device;
a second pair of nodes configured to permit measurement of a second voltage corresponding to a current through a sense resistor connected to a first node of the first pair of nodes;
a measurement circuit electrically coupled to the first pair of nodes and the second pair of nodes; and
control logic configured to:
measure, at a first time using the measurement circuit, the first voltage across the first pair of nodes to produce a first voltage measurement value,
determine an application executing on the electronic device, the application having an operating profile comprising a reference current value;
measure, at second time using the measurement circuit, the first voltage across the first pair of nodes to produce a second voltage measurement value; and
calculate a series resistance in a model of the energy-storage device based on the first voltage measurement value, the second voltage measurement value, and the reference current value.

15. The energy-storage device management unit of claim 14, wherein the measurement circuit further comprises an analog-to-digital converter electrically coupled to the first pair of nodes and the second pair of nodes; and
wherein the analog-to-digital converter is configured to measure the first voltage and the second voltage at the first and second times.

16. The energy-storage device management unit of claim 14, wherein the measurement circuit further comprises:
a voltage-to-current converter, electrically coupled to the second pair of nodes, configured to convert a second voltage to a current; and
a comparator, electrically coupled to the voltage-to-current converter, configured to determine when the current equals the threshold current.

17. The energy-storage device management unit of claim 14, wherein the control logic is further configured to estimate an energy-storage device usage parameter of the energy-storage device based on the model and the calculated series resistance.

18. The energy-storage device management unit of claim 14, wherein the application is a gaming application and the operating profile includes a gaming application specific reference current.

19. The energy-storage device management unit of claim 14, wherein the reference current is application specific.

20. The energy-storage device management unit of claim 16, wherein the voltage-to-current converter produces a scaled value representing the current measurement value; and
the comparator is configured to determine when the scaled value equals the threshold current.
